(19) United States
(12) Patent Application Publication
(10) Pub. No.: US 2005/0284371 A1
(43) Pub. Date: Dec. 29, 2005

(54) Deposition apparatus for providing uniform low-k dielectric

(76) Inventors: Robert S. McFadden, Beaverton, OR (US); Shurong Liang, Hillsboro, OR (US); Vitaly G. Kasperovich, Hillsboro, OR (US); Mandyam A. Sriram, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/881,095

(22) Filed: Jun. 29, 2004

(51) Int. Cl. C23C 16/00

(52) U.S. Cl. 118/715; 427/248.1

(57) ABSTRACT

Improvements in a PECVD chamber to provide better uniformity in film thickness and mechanical strength are described. Less contact surface is provided to the outer edge of the wafer and non-uniform gas distribution occurs through adjustments to the gas distribution plate to provide this uniformity.

### BACKGROUND OF THE INVENTION

The invention relates to the field of semiconductor processing, and more particularly, to an apparatus for chemical vapor deposition, and the like.

### PRIOR ART AND RELATED ART

Several layers of metal interconnect structures are often used in an integrated circuit. Materials with low dielectric constants (low-k) are generally preferred in these layers since they reduce the capacitance between the conductors formed in the layers. Not only does this increase operating speed, but it also helps to reduce power consumption.

Depositing a low-k dielectric layer with a uniform thickness and uniform mechanical strength over an entire wafer has proved to be challenging. This is particularly true for large wafers, such as the 300 millimeter wafers.

### BRIEF DESCRIPTION OF THE DRAWINGS

FIG. 1 is a graph illustrating a distribution of the elastic modulus over a wafer with a prior art deposition apparatus.

FIG. 2 is a graph illustrating the thickness of a low-k dielectric over a wafer with a prior art deposition apparatus.

FIG. 3A is a cross-sectional, elevation view of a prior art wafer holder with a wafer disposed thereon.

FIG. 3B is plan view of the holder of FIG. 3A, with the wafer removed.

FIG. 4 is a drawing of a deposition chamber illustrating a gas distribution “showerhead” and a wafer holder.

FIG. 5 is a plan view of a gas distribution plate used in the apparatus of FIG. 4.

FIG. 6A is a cross-sectional, elevation view of a wafer holder supporting a wafer.

FIG. 6B is a plan view of the wafer holder of FIG. 6A with the wafer removed.

FIG. 7A is a cross-sectional, elevation view of an alternate embodiment of a wafer holder supporting a wafer.

FIG. 7B is a plan view of the wafer holder of FIG. 7A with the wafer removed.

FIG. 8A is a plan view of a wafer holder, illustrating support structure used to modulate deposition thickness.

FIG. 8B is a plan view of an alternate embodiment of the wafer holder of FIG. 8A.

### DETAILED DESCRIPTION

Improvements in an apparatus for depositing materials, particularly a low-k dielectric, is described. In the following description, well-known processing, for instance, chemical vapor deposition processing and chambers for such processing, are not described in detail in order not to unnecessarily obscure the present invention. In other instances, details such as dimensions are given to provide a thorough understanding of the present invention. It will be apparent to one skilled in the art that the present invention may be practiced without these specific details.

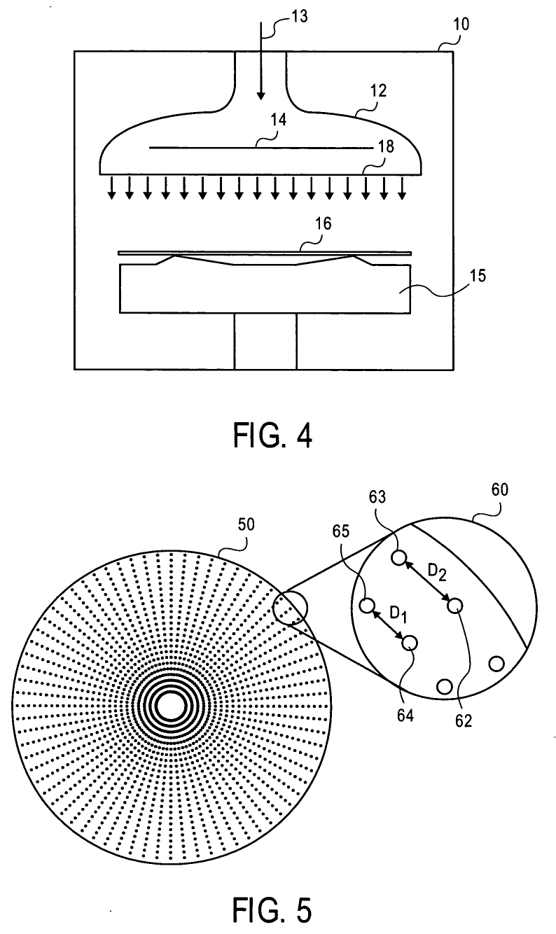

Referring briefly to FIG. 4, a deposition chamber 10 is illustrated having a wafer holder 15 supporting a wafer 16. A gas distribution head 12 receives inlet gas 13 and distributes it onto the wafer 16. The gas is diffused and distributed through a plate 18 having a plurality of openings. Often, an additional buffer plate 14 is used to initially diffuse the gas. The gas distribution head is commonly referred to as a “showerhead.”

The apparatus of FIG. 4 (without the specific wafer holder 15) is often used in semiconductor processing for the chemical vapor deposition of films. In some cases, such as for a low-k dielectric, the temperature at which the film is deposited is kept relatively low to prevent melting of previously deposited metals. A plasma enhanced, chemical vapor deposition (PECVD) is used in such cases. One or more gaseous reactors are directed onto the surface of the wafer, enhanced by the use of electrically charged particles or plasma. Both heat and radio frequency energy are used in the process. One such commercially available apparatus is the ASM Eagle 12 CVD platform. The improvements described below may be used with this platform and others.

The low-k dielectric materials typically have weaker mechanical strengths than higher-k dielectric materials. It is important that the strength of the low-k material be uniform across the entire wafer. If the material is stronger in part of the wafer and weaker in another part, the weaker material may not be sufficiently strong to support, for example, the stresses of chemical-mechanical polishing (CMP), packaging and thermal cycling associated with day-to-day use. The mechanical strength is generally established by considering at least the elastic modulus (i.e., Young's modulus (E)), hardness and cohesive strength of the material.

In addition to the mechanical strength, the low-k dielectric must have a relatively uniform thickness across the entire wafer. One problem that can occur if this thickness varies too greatly, is that of over-etching or under-etching. Over-etching, in a Damascene process, can destroy conductors in underlying layers. Under-etching may prevent a via opening from contacting an underlying conductor.

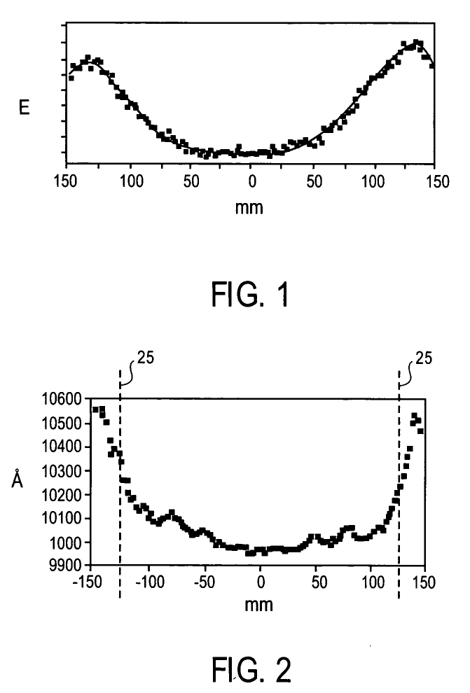

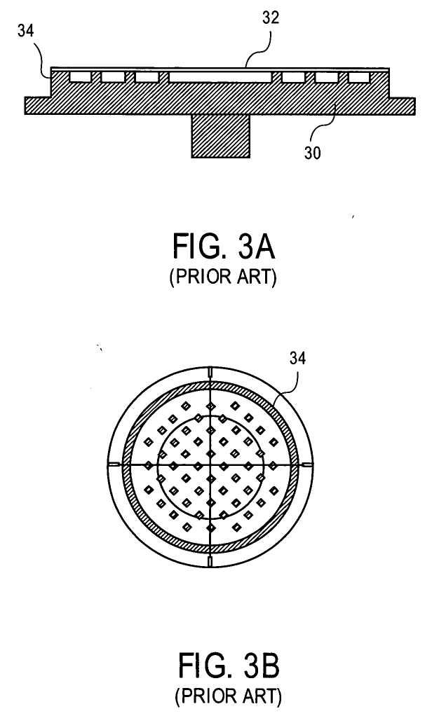

FIG. 1 illustrates the elastic modulus of a low-k film deposited on a 300 millimeter wafer. As can be seen, the modulus was found to be higher at the edge of the wafer and lower near the center of the wafer. This film was deposited with a commercially available (prior art) deposition system, a portion of which will be described in conjunction with FIGS. 3A and 3B.

In the graph of FIG. 1, the elastic modulus is used as an indicator of mechanical strength. As mentioned earlier, this is only one indicator, however, it is representative of the mechanical strength of the film since the other indicators often track this modulus.

FIG. 2 illustrates the film thickness across the surface of the 300 millimeter wafer. As can be seen, the film is thicker near the edge of the wafer and thinner at the wafer's center. For one particular process, the data points beyond the dotted lines 25, are considered unacceptable. The data for this example also was taken for a film deposited with a commercially available (prior art) deposition system.

Both FIGS. 1 and 2 are plotted for the depositing of a carbon-doped silicon dioxide (CDO) layer. This layer is a low-k layer used as an ILD for integrated circuits.

FIGS. 3A and 3B illustrate a wafer holder 30 (also referred to as a “chuck”) supporting a wafer 32 as used in the prior art. An outer annular support 34 has an outside diameter approximately equal to the diameter of the wafer 32.

During the deposition of a film, it was found that a 1% increase in the RF power increased the deposition rate by 1.84 Å per second in one process. Additionally, a 1% increase in the wafer holder temperature decreased the deposition rate by 1.01 Å per second. The wafer holder provides heat to the wafer as well as RF power.

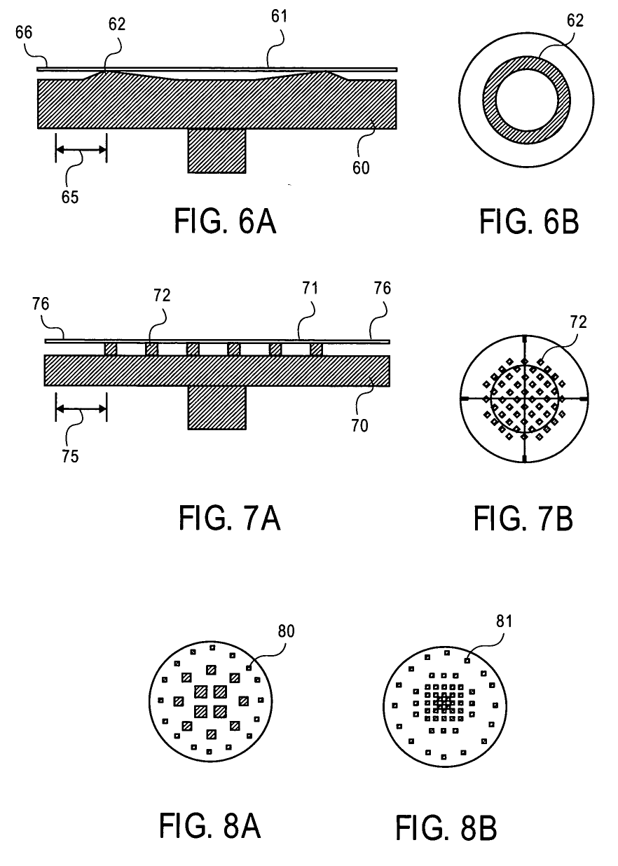

It was determined that by leaving the peripheral region or edge of the wafer unsupported, better uniformity in film thickness results. This is shown by FIG. 6A, where the wafer holder 60 includes an annular support member 62 having an outer diameter less than the wafer 61. As can be seen, the outer region 66 of the wafer 61 is unsupported. This results in less energy being provided to this region of the wafer, which reduces a significant portion of the unwanted thickening of the layer in this region. For a 300 millimeter wafer, the distance 65, which is the unsupported distance, is approximately 50 millimeters or greater. Thus, the outside diameter of the annular support 62 is approximately 200 millimeters, or less for a 300 millimeter wafer.

In an alternate embodiment of the wafer holder of FIG. 6A, a plurality of support members 72 are used. Once again, however, the wafer 71 is unsupported along its edge 76. As shown by the dimension 75, the distance between the edge of the wafer 71 and the support members closest to the edge of the wafer, are approximately 50 millimeters or greater for a 300 millimeter wafer.

In FIG. 5, the plate 18 of FIG. 4 is shown with a distribution of openings in the plate in accordance with one embodiment of the present invention. It has been determined that having a distribution of openings, such that there are fewer openings per unit area near the outer edge of the plate 18, when compared to the center of the plate, improves the uniformity of the mechanical strength of the low-k film.

As can be seen in the enlarged portion 60 of the plate 50, the distance D1 is less than the distance D2. Thus, the openings 62 and 63 are further apart than the openings 64 and 65. This distribution has found to increase the deposited material strength in the central part of the wafer, and decrease it towards the edge of the wafer when compared to a plate with uniformly distributed openings. This results in a more uniform mechanical strength.

It is theorized that by having this non-uniform distribution, the velocity of the gases from the plate are higher in the central portions of the plate, and lower towards the edge of the plate. This in turn, causes the mechanical strength to be greater in the central portion of the film, and less in the outer edge of the film when compared to a film formed with a plate having uniformly distributed opening. Thus, compensation is provided for the non-uniform E shown in FIG. 1.

For a 300 millimeter wafer, the plate 50 has a diameter of approximately 340-350 millimeters, and the openings such as openings 62-65 have a uniform diameter of approximately 0.5 millimeters. Toward the edge of the plate 18, D2 may be equal to 6-10 mm, and D1 in the center of the plate may be equal to 3-5 mm, by way of example.

FIG. 8A and 8B illustrates wafer holders where some supports 80 in FIG. 8A, and supports 81 in FIG. 8B, are provided at or near the wafer edge. This is in contrast to the continuous support provided by the prior art annular member 34 of FIG. 3A and 3B. Thus, less energy is provided to the edge of the wafer than is the case of FIG. 3A and 3B. However, more energy is provided than by the wafer holder embodiments of FIGS. 6 and 7.

The wafer holder of FIGS. 8A and 8B allows for the modulation of a thickness of the film towards the edge of the wafer. A target can be set for the films thickness at the edge of the wafer and then provided, for example, by empirically trying different numbers and diameters for the supports 80 and 81. This will allow the fabrication of a controlled thicker layer at the edges than at the central section of the wafer.

A layer, having increased thickness at the edge which can be selected may be useful. By way of example, where a particular etching process etches more rapidly at the edge of the wafer than the center of the wafer may need such non-uniformity. A slightly thicker film at the edge of the wafer then compensates for the fact that greater etching occurs in this region.

Thus, improvements, particularly for a PECVD process, have been described. By adjusting the supports for the wafer, and thereby adjusting the distribution of the energy imparted to the wafer, more uniformity in film thickness can be obtained. By adjusting the gas distribution across the wafer, more uniformity in the mechanical strength of the film can be obtained.

1. An apparatus comprising:
a chamber;
a wafer holder disposed in the chamber; and
a gas distribution plate having a plurality of openings facing the wafer holder, the openings being distributed such that there are fewer openings per unit area near an outer edge of the plate than at a center of the plate.

2. The apparatus defined by claim 1, wherein the plate has a diameter of approximately 300 millimeters or greater.

3. The apparatus defined by claim 2, wherein the openings have a diameter of approximately 0.5 millimeters.

4. The apparatus defined by claim 1, wherein the wafer holder supports a wafer on an annular support, the annular support having an outside diameter less than the diameter of a wafer supported by the wafer holder.

5. The apparatus defined by claim 4, wherein the wafer holder is adapted to receive wafers of approximately 300 millimeters in diameter, and the outside dimension of the annular support is approximately 200 millimeters or less.

6. The apparatus defined by claim 1, wherein the wafer holder is adapted to receive a wafer and includes a plurality of supports upon which the wafer rests.

7. The apparatus defined by claim 6, wherein the supports are displaced from the edge of a wafer engaging the wafer holder by a distance of approximately 50 millimeters or more.

8. An apparatus comprising:
a chamber;
a gas distribution plate having a plurality of openings; and
a wafer holder disposed in the chamber facing the openings of the gas distribution plate, the wafer holder having an annular support upon which a wafer rests, the annular support being displaced from the edge of the wafer engaging the holder.

9. The apparatus defined by claim 8, wherein the wafer holder receives a 300 millimeter wafer.

10. The apparatus defined by claim 9, wherein the annular support has a diameter of approximately 200 millimeters or less.

11. The apparatus defined by claim 8, wherein the openings of the plate are distributed such that there are fewer openings per unit near an outer edge of the plate than at the center of the plate.

12. The apparatus defined by claim 11, wherein the plate has a diameter of approximately 300 millimeters or greater.

13. The apparatus defined by claim 12, wherein the openings have a diameter of approximately 0.5 millimeters.

14. An apparatus comprising:
a chamber;
a wafer holder disposed in the chamber, the wafer holder having an annular support upon which a wafer rests, the annular support being displaced from the edge of the wafer engaging the holder; and
a gas distribution plate having a plurality of openings facing the wafer holder, the openings being distributed such that there are fewer openings per unit area near an outer edge of the plate than at a center of the plate.

15. The apparatus of claim 14, wherein the plate has a diameter of approximately 300 millimeters or greater.

16. The apparatus of claim 14, wherein the wafer holder is adapted to receive wafers of approximately 300 millimeters in diameter, and the outside dimension of the annular support is approximately 200 millimeters or less.

17. A method for selecting the thickness of a film at the edge of a wafer deposited in a PECVD chamber comprising:
reducing contact surface between the wafer and the wafer holder at the edge of the wafer; and
forming a film on the wafer with the reduced area.

18. The method defined by claim 17, wherein reducing the contact surface comprises, providing a plurality of support members spaced apart from one another to support the wafer.

19. The method defined by claim 17, wherein reducing the contact surface comprises providing an annular support having an outside diameter less than the diameter of the wafer.
